(19) United States
(12) Patent Application Publication
(10) Pub. No.: US 2020/0272905 A1
(43) Pub. Date: Aug. 27, 2020

(54) ARTIFICIAL NEURAL NETWORK COMPRESSION VIA ITERATIVE HYBRID REINFORCEMENT LEARNING APPROACH

(71) Applicant: GE Precision Healthcare LLC, Milwaukee, WI (US)

(72) Inventors: Venkata Ratnam Saripalli, Danville, CA (US); Ravi Soni, San Ramon, CA (US); Jiahui Guan, San Ramon, CA (US); Gopal B. Avinash, San Ramon, CA (US)

(21) Appl. No.: 16/450,474

(22) Filed: Jun. 24, 2019

Related U.S. Application Data
(60) Provisional application No. 62/810,543, filed on Feb. 26, 2019.

(51) Int. Cl. G06N 3/08; H03M 7/30

(52) U.S. Cl. CPC G06N 3/082; H03M 7/702

(57) ABSTRACT

Systems and computer-implemented methods for facilitating automated compression of artificial neural networks using an iterative hybrid reinforcement learning approach are provided. In various embodiments, a compression architecture can receive as input an original neural network to be compressed. The architecture can perform one or more compression actions to compress the original neural network into a compressed neural network. The architecture can then generate a reward signal quantifying how well the original neural network was compressed. In (α)-proportion of compression iterations/episodes, where α∈[0,1], the reward signal can be computed in model-free fashion based on a compression ratio and accuracy ratio of the compressed neural network. In (1−α)-proportion of compression iterations/episodes, the reward signal can be predicted in model-based fashion using a compression model learned/trained on the reward signals computed in model-free fashion. This hybrid model-free-and-model-based architecture can greatly reduce convergence time without sacrificing substantial accuracy.

### TECHNICAL FIELD

The subject disclosure relates to artificial neural network compression and, more specifically, to facilitating automated compression of artificial neural networks via reinforcement learning.

### SUMMARY

The following presents a summary to provide a basic understanding of one or more embodiments of the innovation. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, systems, computer-implemented methods, apparatus and/or computer program products that facilitate neural network compression via an iterative hybrid reinforcement learning approach are described.

Artificial neural networks (hereafter “neural networks” or “networks”) are a computational framework for implementing machine learning (e.g., the teaching of a computer system to perform a specific task without explicit instructions unique to that task). Inspired by biology, neural networks include multiple, interconnected computational units called neurons. The networks are usually organized into a sequence of layers (e.g., an input layer, an output layer, and optionally one or more hidden layers between the input and output layers), with each layer containing one or more of the neurons. Generally, neural networks have fully-connected feedforward topologies (e.g., each neuron in a given layer receives input from every neuron in the preceding layer and sends output to every neuron in the succeeding layer). However, the networks need not be fully-connected (e.g., convolutional neural networks), and other topologies are possible (e.g., short-cut topologies, direct/indirect recurrent topologies, lateral recurrent topologies, and so on).

The general operation of a single neuron is as follows: a neuron receives a vector input (e.g., the vector of scalar activation values of all neurons in the preceding layer); applies a propagation function (e.g., weighted sum) to the vector input to yield a scalar net input; optionally adds a bias value to the scalar net input; computes a scalar activation value by applying a nonlinear activation function (e.g., sigmoid function, softmax function, hyperbolic tangent, and so on) to the scalar net input; and finally outputs its own scalar activation value to the neurons in the succeeding layer. This mathematical transformation between two connected layers can be represented via matrix notation as:

\vec{a}^{(L)}=f(W_{L}\vec{a}^{(L-1)}+\vec{b}^{(L)})

where \vec{a}^{(L)} represents the vector of activation values for all neurons in layer L, \vec{a}^{(L-1)} represents the same for all neurons in layer L−1, \vec{b}^{(L)} represents the scalar bias values of the neurons in layer L, W_{L} represents the weight matrix containing the scalar weight values for all connections to the neurons in layer L, and f represents the nonlinear activation function.

The weights in W_{L} and the biases in \vec{b}^{(L)} are what enable neural networks to recognize patterns. Specifically, during training of the neural network (e.g., supervised training based on input data with known/desired output values), the weights and biases can be initialized randomly and then optimized (e.g., through cost function minimization via backpropagation, stochastic gradient descent, and so on). Once trained, the network's optimized weights and biases allow it to consistently identify particular patterns in inputted data sets, which patterns it learned from the training data. Indeed, a fully-trained neural network can achieve impressive pattern recognition capabilities, and thus can be effectively applied in many fields (e.g., character recognition, audio recognition, computer vision, facial recognition, voice recognition, cancer cell detection, EEG analysis, ECG analysis, X-ray evaluation, MRI evaluation, CAT scan evaluation, ultrasound analysis, and so on).

Since the effectiveness of a neural network can increase with its number of layers/neurons, advanced neural networks have become deeper and larger, thus requiring more and more memory/speed resources for implementation. But, the hardware constraints of many smart devices (e.g., smart phones, personal computers, self-driving cars, autonomous robots, automated medical diagnostics, and so on) can fail to meet these requirements. Compressed neural networks (e.g., smaller networks that exhibit the accuracy/functionality of deeper networks without requiring as much hardware memory/speed) can ameliorate this problem.

Neural network compression is conventionally performed via knowledge distillation (e.g., training a small network to mimic a large, fully-trained network), channel pruning (e.g., zeroing irrelevant/redundant connection weights and keeping only the weights that contribute to the network's output, and/or removing neurons/layers altogether), quantization (e.g., rounding, truncating, or reducing the number of bits representing weights in the network), and so on. Unfortunately, these methods are traditionally manual, time-intensive, and require domain experts and/or carefully hand-crafted network architectures. Not only is hand-crafting the network a non-trivial task (e.g., deep networks can have tens, hundreds, or even thousands of layers, making the space of all possible compressed networks almost intractably huge), but it also makes it difficult to determine whether an optimal network has been created.

Although some automated compression methods exist, they generally utilize only model-free reinforcement learning (e.g., N2N learning, AMC engine compression, and so on), and thus can require very many training trials (e.g., millions in some cases) to converge to an optimal compression policy. Moreover, any automated compression systems that instead rely only on model-based reinforcement learning (which are not conceded to exist), while faster, would be particularly sensitive to model bias, and would thus be only as accurate as the environmental models they use.

The subject claimed innovation bridges the gap between these two automated methods/systems of neural network compression, thus achieving the superior accuracy of model-free reinforcement learning compression with the shorter convergence times of model-based reinforcement learning compression.

According to one or more embodiments, an artificial neural network compression system can comprise a processor that can execute computer-executable instructions stored on a computer-readable memory. In some embodiments, the system can include a reinforcement learning (“RL”) agent component that can determine, via a compression policy (e.g., a probabilistic mapping of states to compression actions), which compression actions to perform. The system can include a model-free component that can, in some embodiments, comprise a first state component. The first state component can receive electronic data indicating a state (e.g., number of layers, number of neurons, number/values of parameters, specific characteristics about a particular layer, and so on) of a neural network to be compressed. In various embodiments, the model-free component can have a first action component that can perform one or more compression actions determined by the RL agent component (e.g., layer removal, neuron removal, parameter/weight removal, parameter/weight adjustment, and so on) on the neural network to compress the neural network into a compressed neural network. The system can also include a model-based component that can comprise, in various embodiments, a second state component that can receive electronic data indicating a state (e.g., number of layers, number of neurons, number/values of parameters, specific characteristics about a particular layer, and so on) of the neural network to be compressed. In various embodiments, the model-based component can also include a second action component that can perform one or more compression actions determined by the RL agent component (e.g., layer removal, neuron removal, parameter/weight removal, parameter/weight adjustment, and so on) on the neural network to compress the neural network into a compressed neural network. In one or more embodiments, the model-free component can compute, in some proportion of iterations (e.g., (α)-proportion of the time that compression actions are performed, where α∈[0,1]), a first reward signal, which can quantify how well the neural network was compressed. The first reward signal can be based on a compression ratio and a model performance metric (e.g., an accuracy ratio) of the compressed neural network for the first state component and the first action component. In various embodiments, the model-based component can predict, in some remaining proportion of compression iterations (e.g., (1−α)-proportion of the time that compression actions are performed), a second reward signal that can quantify how well the neural network was compressed. The second reward signal can be based on a compression model learned from the first state component and the first action component (e.g., a compression model trained on the model-free output). In various embodiments, the RL agent component can iteratively update the compression policy based on one or more first reward signals computed by the model-free component and/or one or more second reward signals predicted by the model-based component (e.g., update the policy using the model-free reward signal in (α)-proportion of compression iterations/episodes, and update the policy using the model-based reward signal in (1−α)-proportion of compression iterations/episodes). The RL agent component can, in some cases, update (e.g., via policy gradient methods) the compression policy until an optimal compression policy is substantially approximated (e.g., convergence).

According to one or more embodiments, a computer-implemented method for compressing artificial neural networks can comprise a series of acts. The computer-implemented method can include receiving as input an original neural network to be compressed. The computer-implemented method can also include performing one or more compression actions (e.g., layer removal, neuron removal, parameter/weight removal, parameter/weight adjustment, and so on) according to a reinforcement learning (RL) agent (e.g., a probabilistic mapping of states to compression actions) to compress the original neural network into a compressed neural network. The computer-implemented method can further include generating a reward signal that quantifies how well the original neural network was compressed. In various embodiments, the generating the reward signal can be performed by computing, in some proportion of iterations (e.g., (α)-proportion of the time that compression actions are performed, where α∈[0,1]), the reward signal in model-free fashion based on a compression ratio and an accuracy ratio of the compressed neural network. In various embodiments, the generating the reward signal can be performed by predicting, in some remaining proportion of compression iterations (e.g., (1−α)-proportion of the time that compression actions are performed), the reward signal in model-based fashion based on a compression model. In some embodiments, the compression model can be learned from one or more of the reward signals computed in model-free fashion (e.g., a compression model trained on the model-free output). The computer-implemented method can, in some cases, include updating (e.g., via policy gradient methods) the RL agent based on the generated reward signal (e.g., updating the policy using the reward signal computed in model-free fashion in (α)-proportion of compression iterations/episodes, and updating the policy using the reward signal predicted in model-based fashion in (1−α)-proportion of compression iterations/episodes). The computer-implemented method can include iterating respective prior steps (e.g., performing compression actions, generating reward signals, and updating the compression policy) until an optimal compression policy is substantially approximated (e.g., convergence).

According to one or more embodiments, a computer program product that can compress artificial neural networks can comprise a non-transitory computer-readable storage medium having program instructions embodied therewith. The program instructions can be executable by a processing component which can cause the processing component to perform one or more acts. The steps can include having the processing component receive as input an original neural network to be compressed. The steps can also include having the processing component perform one or more compression actions (e.g., layer removal, neuron removal, parameter/weight removal, parameter/weight adjustment, and so on) according to a reinforcement learning (RL) agent (e.g., a probabilistic mapping of states to compression actions) to compress the original neural network into a compressed neural network. In some cases, the steps can include having the processing component generate a reward signal that quantifies how well the original neural network was compressed. In various embodiments, the generating the reward signal can be performed by computing, in some proportion of compression iterations (e.g., (α)-proportion of the time that compression actions are performed, where α∈[0,1]), the reward signal in model-free fashion based on a compression ratio and an accuracy ratio of the compressed neural network. In various embodiments, the generating the reward signal can be performed by predicting, in some remaining proportion of compression iterations (e.g., (1−α)-proportion of the time that compression actions are performed), the reward signal in model-based fashion based on a compression model. In some embodiments, the compression model can be learned from one or more of the reward signals computed in model-free fashion (e.g., a compression model trained on the model-free output). The acts can also include having the processing component update (e.g., via policy gradient methods) the RL agent based on the reward signal (e.g., updating the policy using the reward signal computed in model-free fashion in (α)-proportion of compression iterations/episodes, and updating the policy using the reward signal predicted in model-based fashion in (1−α)-proportion of compression iterations/episodes). The acts can also include having the processing component iterate respective prior steps (e.g., performing compression actions, generating a reward signal, updating the compression policy) until an optimal compression policy is substantially approximated (e.g., convergence).

### DESCRIPTION OF THE DRAWINGS

FIG. 1 illustrates a schematic block diagram of a conventional automated network compression system using model-free reinforcement learning.

FIG. 2 illustrates a flow diagram of a conventional automated network compression method using model-free reinforcement learning.

FIG. 3 illustrates a high-level schematic block diagram of an example, non-limiting system that facilitates automated neural network compression via an iterative hybrid reinforcement learning approach in accordance with one or more embodiments described herein.

FIG. 4 illustrates a flow diagram of an example, non-limiting computer-implemented method that facilitates automated neural network compression via an iterative hybrid reinforcement learning approach in accordance with one or more embodiments described herein.

FIG. 5 illustrates a flow diagram of an example, non-limiting computer-implemented method that facilitates automated neural network compression via an iterative hybrid reinforcement learning approach including a-decay in accordance with one or more embodiments described herein.

FIGS. 6A and 6B illustrate schematic block diagrams of example, non-limiting systems that facilitate automated neural network compression via an iterative hybrid reinforcement learning approach in accordance with one or more embodiments described herein.

FIG. 7 illustrates a schematic block diagram of an example, non-limiting system that facilitates automated neural network compression via an iterative hybrid reinforcement learning approach including an update component in accordance with one or more embodiments described herein.

FIG. 8 illustrates a schematic block diagram of an example, non-limiting system that facilitates automated neural network compression via an iterative hybrid reinforcement learning approach including a reward component in accordance with one or more embodiments described herein.

FIG. 9 illustrates a schematic block diagram of an example, non-limiting system that facilitates automated neural network compression via an iterative hybrid reinforcement learning approach including a deep neural network in accordance with one or more embodiments described herein.

FIG. 10 illustrates a schematic block diagram of an example, non-limiting system that facilitates automated neural network compression via an iterative hybrid reinforcement learning approach including a machine learning component in accordance with one or more embodiments described herein.

FIG. 11 illustrates a schematic block diagram of an example, non-limiting system that facilitates automated neural network compression via an iterative hybrid reinforcement learning approach including a value component in accordance with one or more embodiments described herein.

FIG. 12 illustrates pseudocode of an example, non-limiting computer-implemented algorithm that facilitates automated neural network compression via an iterative hybrid reinforcement learning approach in accordance with one or more embodiments described herein.

FIG. 13 illustrates a block diagram of an example, non-limiting operating environment in which one or more embodiments described herein can be facilitated.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Since advanced neural networks have consistently gotten deeper and larger, they require greater hardware capabilities (e.g., memory, speed, and so on) for proper implementation. Unfortunately, smart devices in general, and smart medical devices in particular, often do not meet these heightened hardware requirements. Examples of smart medical devices that could benefit from neural network implementation include smart diagnostic/monitoring devices (e.g., smart sensors that can monitor patient heartrate, blood pressure, breathing, temperature, insulin level, and the like to detect maladies; smart image-analyzers that can evaluate X-rays, MRI scans, CAT scans, ultrasound images, and so on to identify infirmities; smart toilets that can analyze a patient's biological waste for signs of disease; smart beds that can detect occupancy and attempts of occupants to rise; smart surveillance cameras that can determine when an unaccompanied patient has fallen or is struggling; and the like), smart rehabilitation devices (e.g., smart braces, exoskeletons, and/or prostheses that can monitor and/or react to patient motion and forces, and the like), smart therapeutic devices, and so on. Although full-size neural networks often cannot be properly implemented on such devices, sufficiently compressed networks can be. However, a problem in the prior art is that most conventional compression architectures/methods are manual, and that the available automated architectures/methods either take too long to converge (e.g., compression via model-free-only reinforcement learning) or are uniquely susceptible to bias (e.g., compression via model-based-only reinforcement learning, though this is not conceded to exist).

Various embodiments of the present innovation can provide solutions to this problem in the art. One or more embodiments described herein include systems, computer-implemented methods, apparatus, and/or computer program products that facilitate automated neural network compression. More specifically, one or more embodiments pertaining to automated neural network compression via an iterative hybrid reinforcement learning approach (also called “data-driven dyna model compression” or “D3MC”) are described. For example, in one or more embodiments, a compression architecture, which can be modeled as a Markov Decision Process, can receive an original neural network (also called the “teacher network”) to be compressed. In various embodiments, the teacher network can be any type of fully- and/or partially-trained neural network with any type of topology (e.g., feedforward network, radial basis network, deep feedforward network, recurrent network, long/short term memory network, gated recurrent unit network, auto encoder network, variational auto encoder network, denoising auto encoder network, sparse auto encoder network, Markov chain network, Hopfield network, Boltzmann machine network, restricted Boltzmann machine network, deep belief network, deep convolutional network, deconvolutional network, deep convolutional inverse graphics network, generative adversarial network, liquid state machine network, extreme learning machine network, echo state network, deep residual network, Kohonen network, support vector machine network, neural Turing machine network, and so on). The compression architecture can, in one or more embodiments, compress the teacher network by iteratively performing one or more designated actions (e.g., layer removal, layer shrinkage, parameter adjustment, and so on), with each action deterministically changing the state (e.g., number of layers, number of neurons, number/values of weights/biases, and so on) of the network being compressed (also called the “student network”). The compression architecture can choose from among the designated actions by following a policy (e.g., a probabilistic mapping of states to actions) implemented by an RL agent. In one or more embodiments, the policy can be parameterized, non-parameterized/tabular, stochastic, deterministic, and so on. Moreover, the policy, in various embodiments, can be initialized in any way and iteratively optimized (e.g., via policy gradient methods, and so on), resulting in a policy that generally chooses the best (e.g., state-value maximizing and/or action-value maximizing) action, given the current state of the student network, thereby compressing the student network while maintaining comparable accuracy to the teacher network. In various embodiments, the compression architecture can exhibit a dyna structure; that is, the policy can receive feedback from both a model-free reinforcement learning component (e.g., computes reward based on compression ratio and accuracy ratio of a fully-compressed student network) and a model-based reinforcement learning component (e.g., predicts reward of potential actions based on a model of the environment). Such a structure contrasts sharply with conventional automated network compression architectures, which rely solely on model-free reinforcement learning. In some embodiments, the model-based component can learn and improve the environmental model by receiving tuples (e.g., final state of compressed student network and associated reward) from the model-free component, thereby eliminating the need for bias-inducing assumptions about the model. By incorporating both the model-free and model-based components, the subject claimed innovation can avoid searching redundant state-action space, and thus can achieve the accuracy (e.g., optimally compressed student networks) of model-free-only compression systems/methods with the quicker speeds/run-times of model-based-only compression systems/methods (which are not conceded to exist), thereby addressing the shortcomings of prior art compression automation.

In other words, the embodiments described herein relate to systems, computer-implemented methods, apparatus, and/or computer program products that employ highly technical hardware and/or software to provide concrete technological solutions to concrete technological problems in the field of automated neural network compression. Again, conventional systems/methods for automated compression of neural networks primarily use model-free-only reinforcement learning, meaning that they achieve sufficiently accurate results at the expense of requiring significantly many training trials. Moreover, automated network compression that utilizes model-based-only reinforcement learning (which are not conceded to exist) would compress networks more quickly and with fewer training trials, but at the expense of decreased accuracy and/or increased bias inherent in the environmental model used. The present innovation provides a neural network compression architecture/pipeline that is structurally different from conventional automated compression pipelines and that reduces compression training-time without significant loss in accuracy. These technical improvements, which are more thoroughly described below, are not abstract, are not merely laws of nature or natural phenomena, and cannot be performed by humans without the use of specialized, specific, and concrete hardware and/or software.

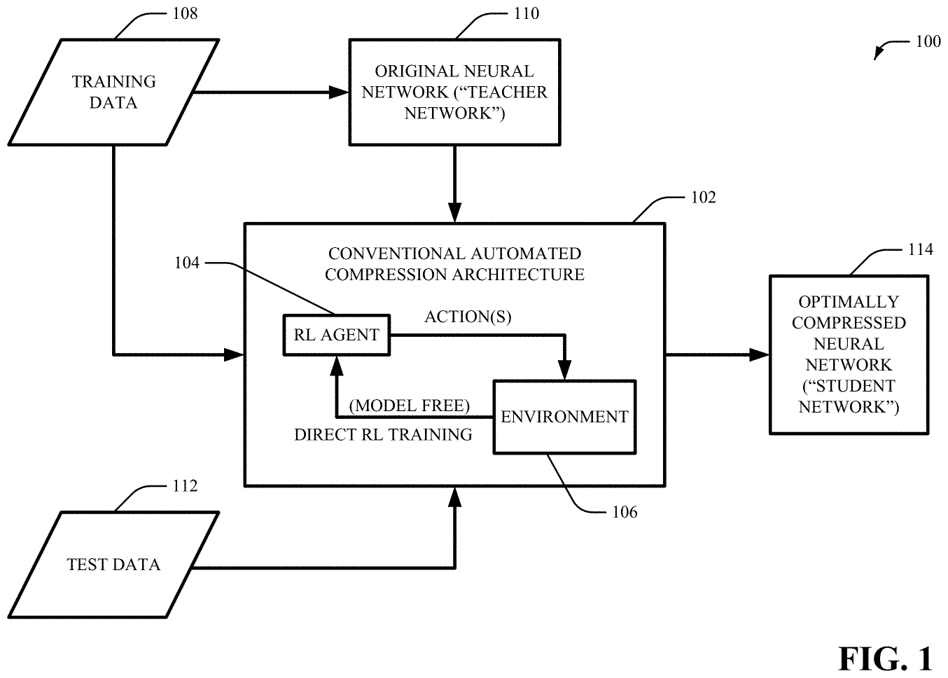

Now, consider the drawings. FIG. 1 illustrates a schematic block diagram of a conventional automated network compression system 100 using model-free reinforcement learning. As shown, the compression system 100 includes conventional automated compression architecture 102 that receives an original neural network (called the “teacher network”) 110 and outputs a compressed neural network (called the “student network”) 114. The compression architecture 102 compresses the teacher network 110 into the student network 114 by iteratively applying one or more compression actions (e.g., layer removal, parameter removal, weight adjustment, and so on) to the environment 106 (e.g., the network being compressed). The compression architecture 102 selects compression actions to perform according to an RL agent 104 (e.g., which can use a policy, a stochastic mapping from states to actions). Once a full episode of compression actions has been performed, meaning that a fully compressed student network 114 has been created, the compression architecture 102 utilizes a model-free reinforcement learning approach to compute a reward that characterizes how well or poorly the student network 114 has been compressed. The reward is usually a function of the compression ratio, comparing the size of the student network 114 to that of the teacher network 110, and the accuracy ratio, comparing the accuracy of the student network 114 to that of the teacher network 110. The compression ratio is simply a function of the number of parameters/layers in the compressed student network 114 and the number of parameters/layers in the teacher network 110. The accuracy ratio is obtained by comparing the results of the teacher network 110 in response to given training data 108 to the results of the student network 114 in response to the same training data 108. In some cases, the compressed student network 114 can also be fed test data 112 to determine its level of accuracy. After the environment 106 computes the reward, the RL agent 104 can update (e.g., improve its policy via policy gradient methods) based on the reward. Such a method of updating a policy based on received rewards is called direct RL training. This overall process of performing a sequence of compression actions, computing a reward based on the characteristics of the compressed network, and updating the policy of the RL agent 104 based on the reward is iterated until the policy converges (e.g., is optimized or approximately optimized); that is, until a cumulative reward function is maximized. At that point, the RL agent 104 can choose the best compression action for any given state, and so the compression architecture 102 outputs the optimally-compressed student network 114.

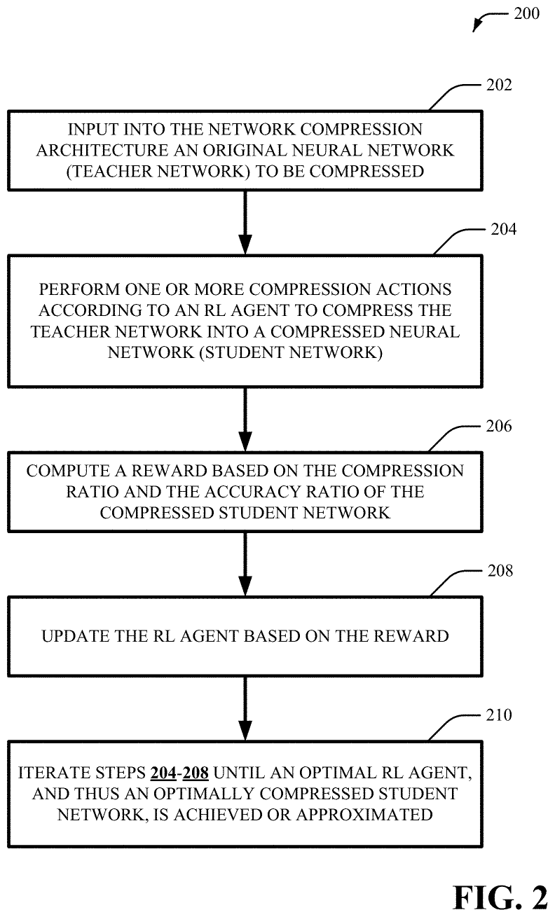

A simplified depiction of this compression process is illustrated in FIG. 2. As shown, FIG. 2 illustrates a flow diagram of a conventional automated network compression method 200 using model-free reinforcement learning. At 202, a network compression architecture receives as input an original neural network (“teacher network”) to be compressed. At 204, the compression architecture performs one or more compression actions, such as layer removal, parameter removal, weight adjustment, and so on, according to a compression policy in order to compress the teacher network into a compressed neural network (“student network”). At 206, the compression architecture computes a reward based on the compression ratio and the accuracy ratio of the compressed student network. At 208, the compression architecture updates the compression policy based on the computed reward. Finally, at 210, the compression architecture repeatedly iterates 204 to 208 until an optimal compression policy, and thus an optimally compressed student network, is achieved or approximated (e.g., convergence).

Again, since conventional compression architectures utilize only model-free reinforcement learning (e.g., model-free direct RL learning in FIG. 1, computing reward in model-free fashion at 206 in FIG. 2), such architectures can generally achieve optimally compressed student networks only after many, many iterations (e.g., millions, in some cases). The present innovation addresses this problem in the prior art by simultaneously incorporating both a model-free compression component and a model-based compression component. This hybrid structure cuts down on the required compression iterations without substantially reducing the accuracy of the finally-compressed student network.

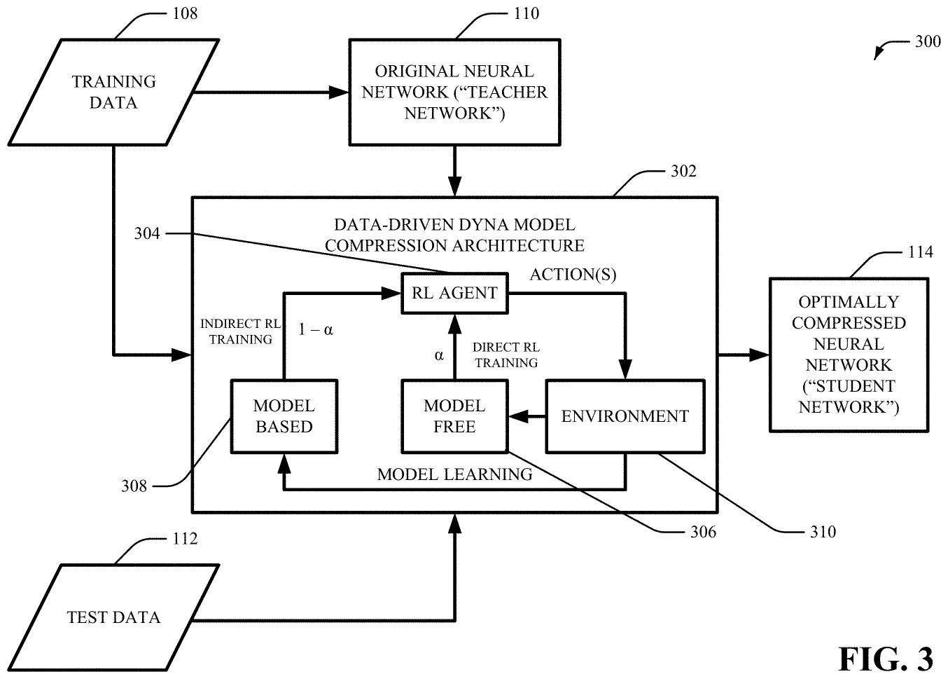

To better understand the subject claimed innovation, consider the remaining figures. FIG. 3 illustrates a high-level schematic block diagram of an example, non-limiting system 300 that facilitates automated neural network compression via an iterative hybrid reinforcement learning approach in accordance with one or more embodiments described herein. As shown in FIG. 3, the system 300 can comprise a data-driven dyna model compression architecture (called the “D3MC architecture”) 302 that can receive an original neural network (“teacher network”) 110 (or, in some embodiments, a copy of a teacher network 110) and output an optimally-compressed neural network (“student network”) 114.

The D3MC architecture 302 can be modeled as a finite Markov decision process (“MDP”). The MDP can be defined by the tuple M={S, A, T, π_{\vec{θ}}, r_{MF}, r_{MB}, γ}. S can represent the state-space, which can include all possible reduced architectures—that is, all possible compressed student networks 114—that can be derived from the teacher network 110. Any student network 114 can be described by its state s∈S, which can include its number of layers, the number of neurons in each layer, the number of weights/parameters in the network, the values of those weights/parameters, the accuracy of the network, and so on. In some embodiments, the state s∈S can instead represent the state of a particular layer in the student network 114, such as the layer type, the number of kernels, the kernel size, the stride, the padding, the trainable parameters in the layer, and so on. In some cases, the state can represent any combination of the aforementioned, and so on. A can represent the action-space, which can include all possible actions that can transform one network architecture into another, such as layer removal, neuron removal, parameter/weight removal, parameter/weight adjustment, and so on. T:S×A→S can represent a transition function that describes how the state of the student network 114 changes based on a previous state and an action taken in that previous state. T can be deterministic since a given compression action a∈A can take a student network 114 from one state s∈S to another state s′∈S without uncertainty. The actions a∈A can be selected by an RL agent according to a compression policy π_{\vec{θ}}:S→A, which is a probabilistic mapping of states to actions with a parameterization of _{\vec{θ}}(e.g., a vector of parameter values that influence the policy output). In one or more embodiments, the policy π can instead be tabular, non-parameterized, and so on. In some cases, the policy can be deterministic. Now, r_{MF}:S→R, where R is the set of real numbers, can represent a model-free reward function that computes a reward based on the state of the student network 114. Similarly, r_{MB}:S→R can represent a model-based reward function that predicts a reward based on the state of the student network 114 and a model of the learning environment. In various embodiments, a reward can be computed after each action a∈A. In various other embodiments, a reward can be computed after a final compressed state sₙ∈S is achieved via a sequence of actions a₀, a₁, . . . , aₙ∈A. These rewards can be used to iteratively update/improve the policy π_{\vec{θ}} (e.g., via policy gradient optimization, REINFORCE policy gradient optimization, dynamic programming, Monte Carlo methods, temporal difference methods, n-type bootstrapping methods, and so on). Finally, γ∈[0,1] can represent a discount factor that determines how heavily future rewards are weighted compared to present rewards, which can influence the policy update process.

As shown, the D3MC architecture 302 can include an RL agent 304 that can use a policy (e.g., π_{\vec{θ}}) to probabilistically select one or more actions from the action-space to compress the teacher network 110 into the student network 114. The actions can be performed by the RL agent 304 on the environment 310 (e.g., the network currently being compressed). In one or more embodiments, the policy can be initialized in any way (e.g., random initialization of parameters in \vec{θ}) and can subsequently be iteratively updated/optimized (e.g., via policy gradient methods, REINFORCE policy gradient optimization, dynamic programming, Monte Carlo methods, temporal difference methods, n-step bootstrapping methods, any variations of the aforementioned, and so on). After performing a sequence/episode of compression actions (e.g., actions a₀, a₁, . . . , aₙ∈A resulting in compressed state sₙ∈S of the student network 114), a reward can be computed and/or predicted to characterize/quantify how well or how poorly the student network 114 was compressed. The RL agent 304 can then iteratively optimize the policy based on the reward (and/or based on a sum of discounted and/or non-discounted future rewards) as mentioned above.

In one or more embodiments, the D3MC architecture 302 can include a model-free reinforcement learning component 306 that can compute a reward based on the compressed state sₙ∈S (e.g., via reward function r_{MF}:S→R). In various embodiments, the model-free reinforcement learning component 306 can compute the reward as a function of the compression ratio, comparing the size of the compressed student network 114 to the size of the original teacher network 110, and of the accuracy ratio, comparing the accuracy of the outputs of the compressed student network 114 to that of the original teacher network 110, or some other model performance metric. Again, the compression ratio can be computed by comparing the number of parameters, layers, and/or neurons in the compressed student network 114 to the number of parameters, layers, and/or neurons in the original teacher network 110. Also, the accuracy ratio can be obtained by comparing the outputs of the original teacher network 110 in response to given training data 108 to the outputs of the compressed student network 114 in response to the same training data 108. Moreover, in some embodiments, test data 112 can be used to determine the accuracy of the compressed student network 114. In one or more embodiments, the D3MC architecture 302 can train the compressed student network 114 via cross-entropy loss and/or distillation loss from the teacher network 110 and based on the training data 108 and/or the test data 112, thereby yielding the accuracy of the compressed student network 110. As mentioned above, this process of performing one or more compression actions, computing a reward based on the compressed state of the student network, and updating the policy based on the reward is called direct RL learning/training.

As shown, in one or more embodiments, the D3MC architecture 302 can also comprise a model-based reinforcement learning component 308 that can predict a reward based on a compressed state of the student network 114 and/or based on contemplated compression actions (e.g., predicting the reward that would occur if the contemplated compression actions were performed). To predict the reward, the model-based reinforcement learning component 308 can, in various embodiments, have a model (e.g., distribution and/or sample model) of the environment 310. In some embodiments, the model (e.g., the function r_{MB}:S→R) can be learned via a machine learning component based on real experience (e.g., the actual rewards generated by the model-free reinforcement learning component). In such cases, when the D3MC architecture 302 computes a reward via the model-free reinforcement learning component 306, that reward and its associated compressed state sₙ∈S can be sent to the model-based reinforcement learning component 308. The model-based reinforcement learning component 308 can, after receiving one or more of these samples (e.g., reward-and-final-state pairs), perform supervised training on its machine learning component (e.g., training the machine learning component to output the given rewards when the given compressed states, and/or similar compressed states, are encountered and/or contemplated). Once such a reward is predicted, the RL agent 304 can be iteratively update/optimize the policy, as described above, based on the predicted reward. This process of performing one or more compression actions, predicting the reward, and updating the policy is called indirect RL learning and/or planning. In one or more embodiments, the model-based reinforcement learning component 308 can perform background planning (e.g., using simulated experience to improve value functions and/or policy) and/or decision-time planning (e.g., using simulated experience to select an action in the current state).

In various embodiments, the D3MC architecture 302 can select an (α)-proportion of its actions in a given compression episode, where α∈[0,1], to be rewarded via the model-free reinforcement learning component 306. Thus, a (1−α)-proportion of its actions in the given compression episode can be rewarded via the model-based reinforcement learning component 308. For example, if α=0.6, then rewards can be computed via the model-free reinforcement learning component 306 about 60% of the time, while rewards can be predicted via the model-based reinforcement learning component 308 about 40% of the time. In one or more embodiments, the value of a can be decayed over time. In such cases, the model-free reinforcement learning component 306 can be used more often during the early compression trials/episodes of the D3MC architecture 302, thereby allowing a robust and unbiased model of the environment to be generated by the model-based reinforcement learning component 308. Consequently, the model-based reinforcement learning component 308 can then be used more often in the later compression trials/episodes, thereby significantly cutting down on convergence time without sacrificing substantial accuracy.

In various embodiments, the rewards predicted by the model-based reinforcement learning component 308 can be used by the RL agent 304 to update/optimize the policy. In various other embodiments, the rewards predicted by the model-based reinforcement learning component 308 can be used to select a compression action at decision-time without updating/optimizing the policy. In some embodiments, a combination of the aforementioned is possible. In any case, a significant training speed-up can be achieved by combining the model-based reinforcement learning component 308 with the model-free reinforcement learning component 306.

In one or more embodiments, the environment 310 can exhibit the following behavior. The environment can accept a list of layers with binary action (e.g., 0 to keep, 1 to remove) per layer from the teacher network 110. The D3MC architecture 302 can receive this list and create a network with the removed layers. The D3MC architecture 302 can then use the original weights/parameters of the teacher network 110 to initialize the student network 114. After initialization, the D3MC architecture 302 can train the student-network 114 with a cross-entropy loss and/or a distillation loss from the teacher network 110. The associated reward can then be computed and/or predicted, as described above. By incorporating a model-based reinforcement learning component 308, the retrain time can be cutdown significantly via predicting the reward signal.

In various embodiments, an actor-critic architecture can be used, in which policy gradient methods are combined with value-function estimation to critique/evaluate the policy.

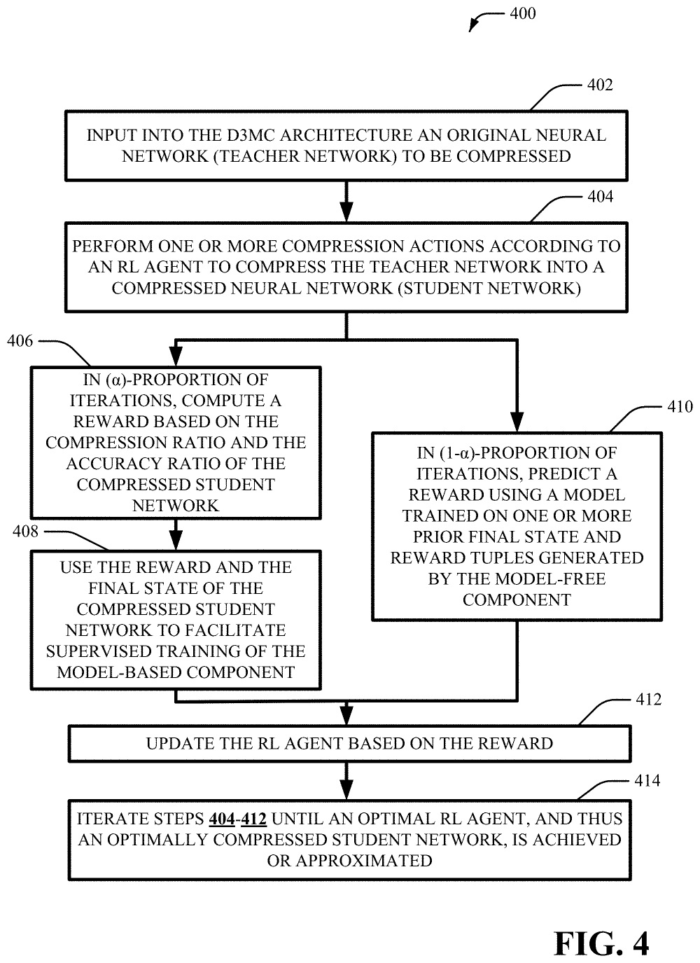

A simplified depiction of this overall process, according to one or more embodiments, is illustrated in FIG. 4. FIG. 4 illustrates a flow diagram of an example, non-limiting computer-implemented method 400 that facilitates automated neural network compression via an iterative hybrid reinforcement learning approach in accordance with one or more embodiments described herein. At 402, a D3MC architecture can receive as input an original neural network (“teacher network”) to be compressed. In some embodiments, the D3MC architecture can receive a copy/duplicate of the original teacher network, such that the original teacher network remains unaltered while the duplicate teacher network is iteratively compressed and becomes the resultant student network. At 404, the D3MC architecture can perform one or more compression actions (e.g., layer removal, neuron removal, parameter/weight removal, parameter/weight adjustment, and so on) according to a compression policy to compress the teacher network into a compressed neural network (“student network”). At 406, in α-proportion of iterations, the D3MC architecture can compute a reward, via a model-free component, based on the compression ratio and the accuracy ratio of the compressed student network. As mentioned above, this reward computation can, in some embodiments, be performed after a sequence of compression actions are taken (e.g., after reaching a compressed state sₙ∈S). In other embodiments, a reward can be computed after each compression action. In one or more embodiments, the compressed student network can be trained using cross-entropy loss and/or distillation loss on the teacher network in order to determine the compressed student network's accuracy. At 408, the D3MC architecture can use the computed reward and the final state of the compressed student network to facilitate supervised training of a model-based component in the D3MC architecture. At 410, in (1−α)-proportion of iterations, the D3MC architecture can predict a reward, via a model-based component, using a model trained on one or more prior final-state-and-reward tuples generated by the model-free component. As mentioned above, in various embodiments, this reward prediction can be computed after a sequence of compression actions and/or after each compression action. At 412, the D3MC architecture can update (e.g., via policy gradient methods, and so on) the compression policy based on the computed and/or predicted reward. Finally, at 414, the D3MC architecture can iterate/repeat 404 to 412 until an optimal compression policy, and thus an optimally compressed student network, is achieved and/or approximated.

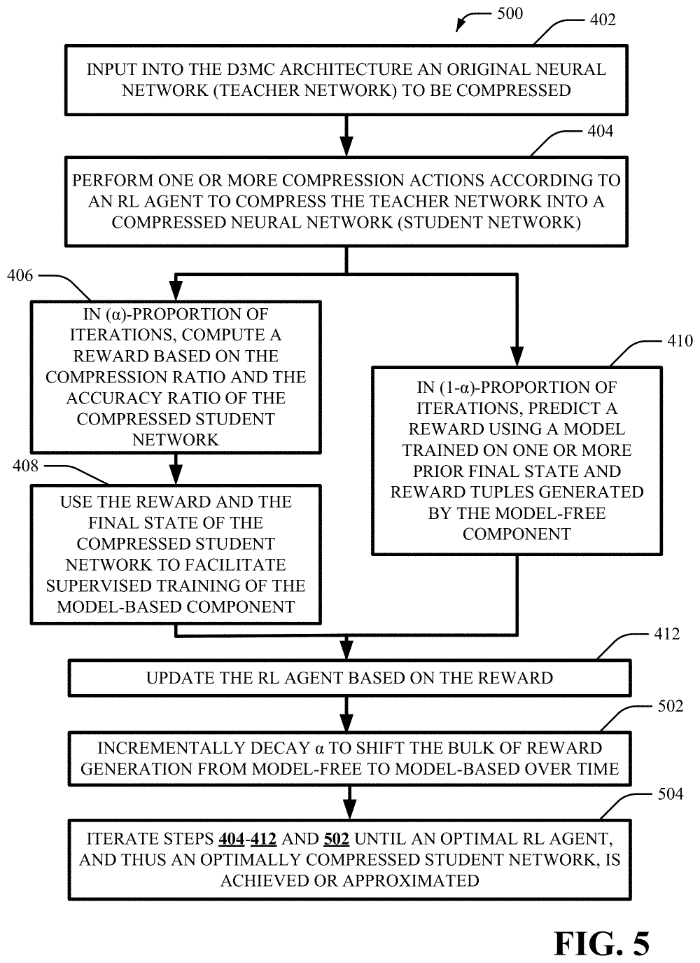

Now consider FIG. 5. FIG. 5 illustrates a flow diagram of an example, non-limiting computer-implemented method 500 that facilitates automated neural network compression via an iterative hybrid reinforcement learning approach including a-decay in accordance with one or more embodiments described herein. As shown, the method 500 can, in various embodiments, have the same operations 402 to 412 as shown in FIG. 4. At 502, the D3MC architecture can, in one or more embodiments, incrementally decay a to shift the bulk of reward generation from the model-free component to the model-based component over time and/or from compression episode to compression episode. Finally, at 504, the D3MC architecture can iterate 404 to 412 and 502 until an optimal compression policy, and thus an optimally compressed student network, is achieved and/or approximated. In other words, the early compression episodes/trials (e.g., sequences of compression actions) of the D3MC architecture can rely more heavily on the model-free component, which can help to generate a robust environmental model in the model-based component via the supervised training of 408. Once a sufficiently robust model has been trained/learned, a can be decayed, which can cause the later compression episodes/trials to rely more heavily on the model-based component. This hybrid structure/pipeline reaps the advantages of both model-free and model-based learning; it enables the D3MC architecture to achieve the compression accuracy of the model-free approaches, without requiring their inordinately long run times.

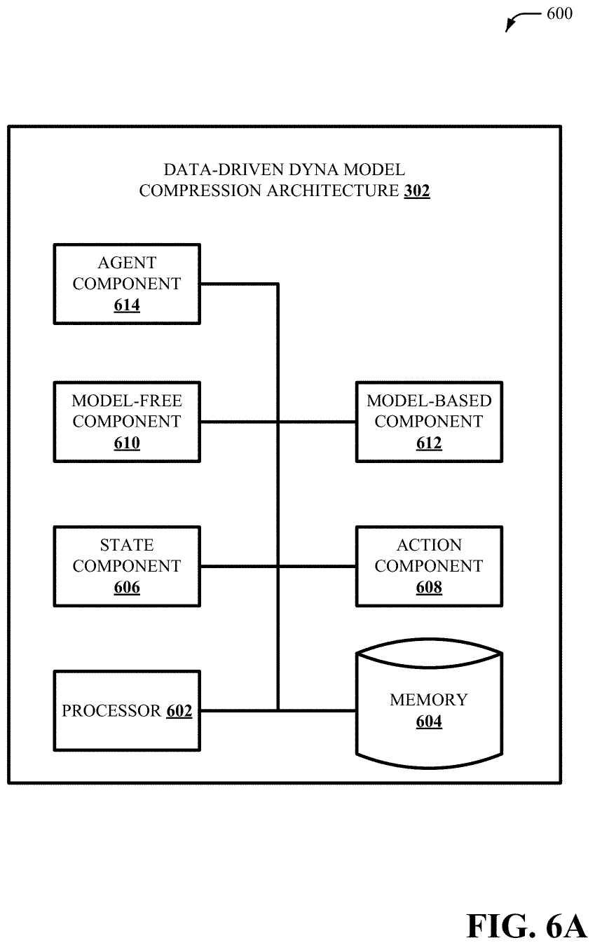

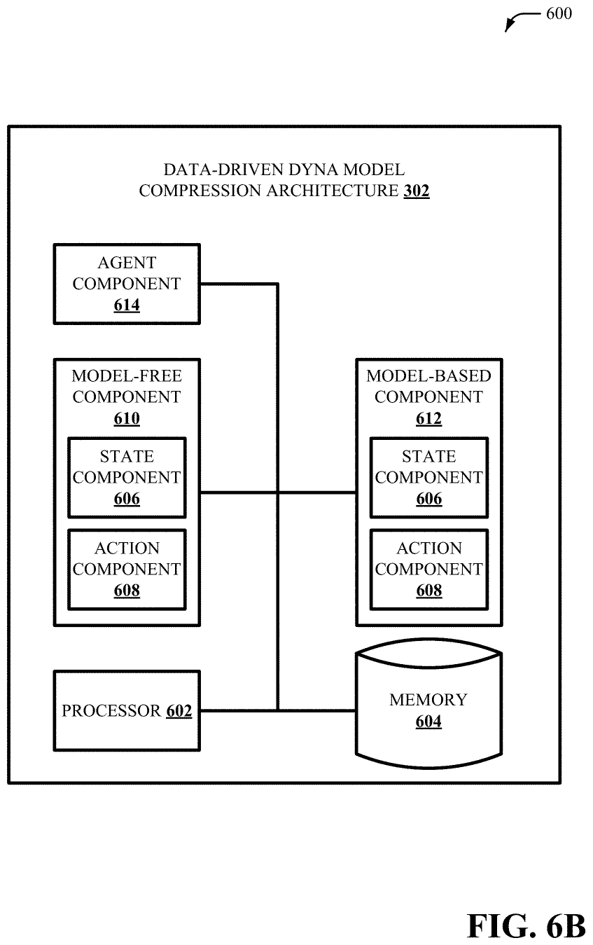

Now, consider FIGS. 6A and 6B. FIGS. 6A and 6B illustrate schematic block diagrams of example, non-limiting systems 600 that facilitate automated neural network compression via an iterative hybrid reinforcement learning approach in accordance with one or more embodiments described herein. As shown in FIG. 6A, the system 600 can include the data-driven dyna model compression (“D3MC”) architecture 302. In one or more embodiments, the D3MC architecture 302 can comprise a processor 602 and a computer-readable memory 604. The computer-readable memory 604 can store computer-executable instructions that can be executed by the processor 602. These instructions and their execution can, in some embodiments, control the execution, operation, and/or functionality of various other components in the D3MC architecture 302.

In one or more embodiments, the D3MC architecture 302 can also include a state component 606 that can receive electronic data signifying the state information of a student network to be compressed. In various embodiments, the state component 606 can receive data indicating the number of layers in the student network, the number of neurons in the student network, the number of parameters/weights in the student network, the values of parameters/weights in the student network, the layer type of a particular layer in the student network, the number of kernels in that layer, the kernel size of that layer, the stride of that layer, the padding of that layer, the number of trainable parameters in that layer, any combination of the aforementioned, and so on. At the beginning of a compression episode, the initial state received by the state component 606 can, in some embodiments, be a state of an original teacher network (e.g., the student network's architecture before any compression has been performed is identical to that of the teacher network, and the structures of any individual layers in the student network before any compression has been performed are identical to those in the teacher network). In one or more embodiments, the state component 606 can electronically receive/read the state information of the student network after each compression action and/or after each compression episode/trial (e.g., a sequence of compression actions). By reading the state information collected by the state component 606, the D3MC architecture 302 can select compression actions to perform on the student network based on the received state information.

As shown, the D3MC architecture 302 can comprise an action component 608 that can perform one or more of a set of designated compression actions on the student network. In various embodiments, the set of designated compression actions can include layer removal, neuron removal, parameter/weight removal, parameter/weight adjustment, and so on. That is, in one or more embodiments, the action component 608 can remove one or more layers from the student network, can remove one or more neurons from the student network, can remove/zero one or more parameters/weights in the student network, can otherwise adjust the values of one or more parameters/weights in the student network, and so on. In some cases, each action performed by the action component 608 can deterministically transform the architecture of the student network from one state s∈S to another s′∈S.

As shown, the D3MC architecture 302 can also comprise an agent component 614. The agent component 614 can use a compression policy (e.g., π_{\vec{θ}}), which can probabilistically map the state information received by the state component 606 to designated compression actions to be performed by the action component 608. That is, the agent component 614 can determine which compression action and/or range of potential compression actions to take when the student network is in a particular state. For example, the agent component 614 can, in some cases, determine that a current state of the student network calls for removing a certain layer in the student network rather than merely removing one or more neurons in the layer or merely adjusting/removing the weights in the layer, and/or vice versa. The agent component 614 can make this determination since the policy assigns a higher probability to the compression action and/or actions that it favors the most. In one or more embodiments, the compression policy of the agent component 614 can be parameterized (e.g., π_{\vec{θ}}), non-parameterized, tabular, stochastic, deterministic, and so on. In cases where the compression policy is parameterized, the compression policy π can be a probabilistic function of one or more parameters (e.g., parameters listed in vector \vec{θ}) and can be optimized (e.g., via policy gradient methods) without consulting a state-value function and/or action-value function, although such a value function can still be incorporated (e.g., actor-critic approaches). As a simple example, a parameterized policy can be a variation of the softmax function as follows:

$$π ( a \vert s , \vec{θ} ) = \frac{{e}^{h ( s , a , \vec{θ} )}}{{Σ}_{b} {e}^{h ( s , b , \vec{θ} )}}$$

where π(a|s, \vec{θ}) means the probability of choosing action a∈A given state s∈S and parameter vector \vec{θ}∈R^{d} for some d<<|S| (e.g., meaning that d is a real number that is significantly less that the number of states in state-space S), and where h:S×A×R^{d}→R is a preference function that assigns to each action, state, and parameter tuple a scalar preference value (e.g., higher for more preferred tuples). Those of ordinary skill in the art will appreciate that any other parameterization of π is in accordance with this disclosure.

As shown, the D3MC architecture 302 can further comprise a model-free component 610 and a model-based component 612. As explained in more detail below, the compression policy of the agent component 614 can be updated/optimized in order to ensure that appropriate compression actions are being performed by the action component 608. In various embodiments, the model-free component 610 and the model-based component 612 can help to facilitate this optimization by computing (e.g., model-free) and/or predicting (e.g., model-based) a reward that characterizes and/or quantifies how well or how poorly the student network was compressed. As mentioned above, such rewards can, in some embodiments, be generated after a sequence of compression actions has fully compressed a student network (e.g., after each compression episode/trial). In other embodiments, such rewards can be generated after each compression action, and so on. Those of ordinary skill in the art will appreciate that much of the above discussion about model-free and model-based reinforcement learning is applicable to model-free component 610 and model-based component 612, respectively.

In various embodiments, the model-free component 610 and the model-based component 612 can each comprise their own state component 606 and action component 608, as shown in FIG. 6B. Those of ordinary skill in the art will appreciate that the above discussion of the state component 606 and the action component 608 can apply to the state and action components depicted in FIG. 6B. For brevity, the remaining disclosure discusses other embodiments in relation to the configurations contemplated in FIG. 6A. However, those of skill will understand that all of this disclosure can be applied equally well to the configurations contemplated in FIG. 6B.

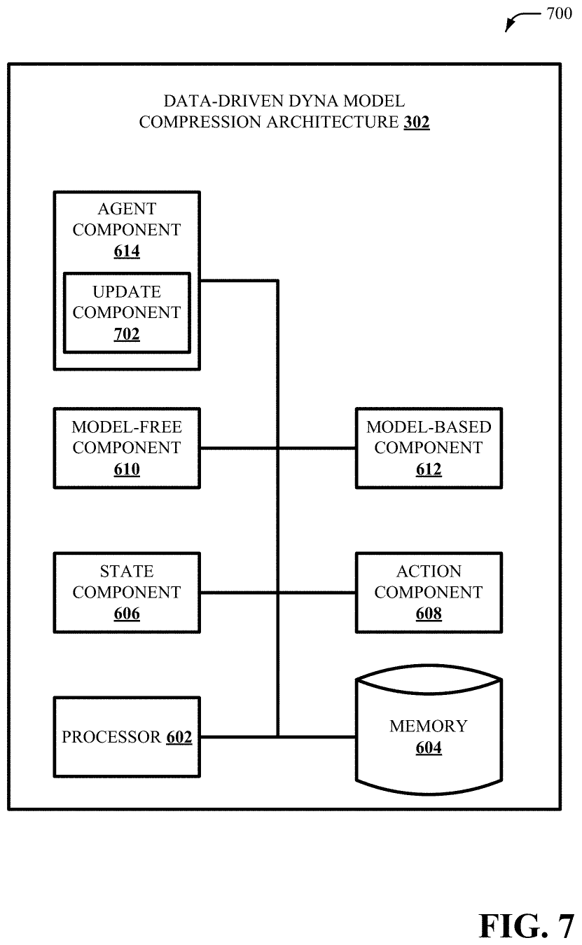

Now, consider FIG. 7. FIG. 7 illustrates a schematic block diagram of an example, non-limiting system 700 that facilitates automated neural network compression via an iterative hybrid reinforcement learning approach including an update component in accordance with one or more embodiments described herein. As shown, the D3MC architecture 302 can, in some embodiments, comprise all the components discussed in relation to FIG. 6A, and can further include an update component 702 that can update/optimize the compression policy π of the agent component 614. As one of ordinary skill in the art will appreciate, the mathematical methods of updating/optimizing the compression policy of the agent component 614 can depend on the type of policy used (e.g., parameterized vs. non-parameterized/tabular, and so on).

In one or more embodiments, the compression policy used by the agent component 614 can be parameterized (e.g., π_{\vec{θ}}). Such a policy can be optimized/updated via policy gradient methods known in the art, such as the REINFORCE family of policy gradient optimization. Such methods can update the compression policy function of the agent component 614 directly, without first calculating a state-value and/or action-value function. These methods generally update the parameter vector \vec{θ} between episodes/time-steps as follows:

\vec{θ}ₜ₊₁=\vec{θ}ₜ+α∇J(\vec{θ}ₜ)

where \vec{θ}ₜ₊₁ is the policy parameter vector at time/episode t+1, \vec{θ}ₜ₊₁ is the policy parameter vector at the current time/episode t, α is the learning rate (usually between 0 and 1), and ∇J(\vec{θ}ₜ) represents the gradient of some performance measure that depends on the parameter vector. In various embodiments, the performance measure gradient can generally be resolved, after application of the policy gradient theorem, as follows:

∇J(\vec{θ}ₜ)=Gₜ∇lnπ(Aₜ|Sₜ, \vec{θ}ₜ)

where Aₜ∈A is an action and/or a sample of an action taken at time/episode t, Sₜ∈S is a state and/or a sample of a state taken at time/episode t, and Gₜ is the expected return (e.g., discounted sum of rewards and/or average reward expected to be received by following the policy). In some embodiments, a state-independent and/or action-independent baseline can be subtracted from Gₜ to reduce variance. Those of ordinary skill in the art will appreciate that the above equations can have many different forms and/or variations depending upon the context (e.g., continuing vs. episodic tasks, on-policy approximation vs. off-policy approximation, notational differences, and so on). Moreover, entirely different update equations can be used. Thus, the above formulas are exemplary only. Those of ordinary skill in the art will understand that any policy gradient optimization method known in the art can be used with one or more embodiments described herein (e.g., stochastic gradient descent/ascent, REINFORCE policy gradient optimization, and so on).

In one or more embodiments, the compression policy can be non-parameterized and/or tabular. In such cases, those of ordinary skill will appreciate that methods other than policy gradient descent/ascent can be used to optimize the policy (e.g., action-value optimization, dynamic programming, Monte Carlo methods, temporal difference methods, n-step bootstrapping methods, SARSA methods, Q-learning methods, any variations and/or combinations of the aforementioned, and so on).

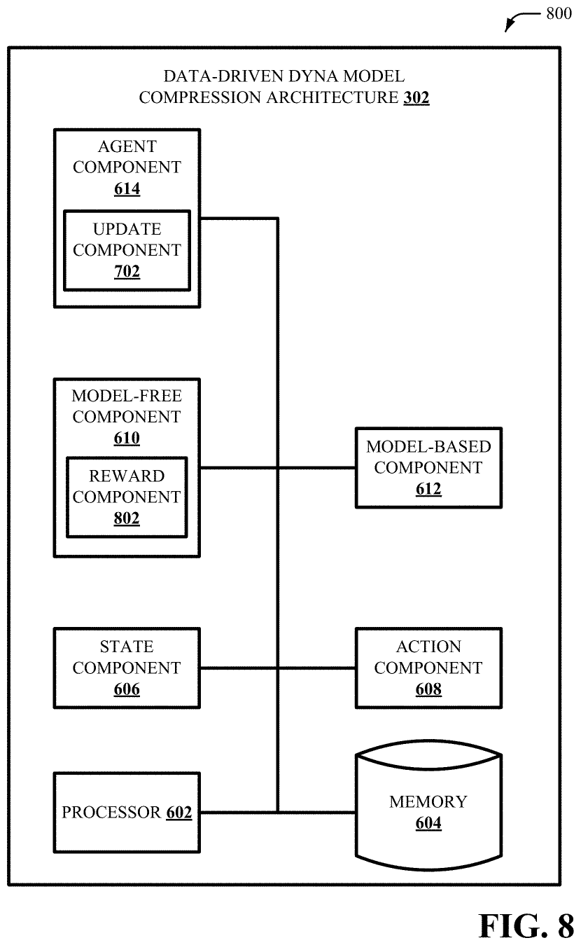

Thus, in one or more embodiments, the updates to the compression policy of the agent component 614 can depend on the expected return (e.g., Gₜ) of following the given policy, and the expected return can itself be a function of the real and/or simulated rewards generated in response to the compressed state(s) of the student network. To better understand how these reward values are generated, consider FIG. 8. FIG. 8 illustrates a schematic block diagram of an example, non-limiting system 800 that facilitates automated neural network compression via an iterative hybrid reinforcement learning approach including a reward component in accordance with one or more embodiments described herein. As shown, the D3MC architecture 302 can, in various embodiments, have the same components as the system 700 in FIG. 7, and can further include a reward component 802 in the model-free component 610. Those of ordinary skill in the art will appreciate that much of the above discussion regarding how model-free approaches compute rewards can be applied to the reward component 802. In various embodiments, the reward component 802 can compute a reward (e.g., via the reward function r_{MF}:S→R) based on the compression ratio and the accuracy ratio of a student network after one or more compression actions have been performed. In one or more embodiments, the reward function can be defined as follows:

r_{MF}=R_{C}R_{A}

where

$${R}_{C} = C ( 2 - C ) , with C = 1 - \frac{\# Par a m e t e r {s}_{s t u d e n t}}{\# Par a m e t e r {s}_{t e a c h e r}}$$

and where

$${R}_{A} = \frac{A c c u r a c {y}_{stud ent}}{A c c u r a c {y}_{teac her}}$$

Here, R_{C} can refer to the compression reward (e.g., higher reward for greater compression) and R_{A} can refer to the accuracy reward (e.g., higher reward for greater accuracy). But multiplying these constituent reward values together, the overall reward for a given compressed student network scales with both the compression and the accuracy of the student network. Now, C can represent the compression ratio itself, which, as shown, can be a function of the number of parameters in the compressed student network (e.g., # Parameters_{student}) and the number of parameters in the original teacher network (e.g., # Parameters_{teacher}). Moreover, the accuracy reward R_{A} can simply be the ratio of the accuracy of the compressed student network (e.g., Accuracy_{student}) to the accuracy of the original teacher network (e.g., Accuracy_{teacher}). As mentioned above, the accuracy of the student and teacher networks can be determined by respectively training the student and teacher networks on training data 108 and/or test data 112 and then comparing their results to the desired/correct results (e.g., supervised training). Those of ordinary skill in the art will appreciate that other methods are possible (e.g., training via cross-entropy loss and/or distillation loss, and so on). Those of skill will also understand that the reward component 802 can compute rewards using different parameters, variables, formulas, and so on. Regardless of the particular formula used, the reward component 802 can drive direct RL learning of the D3MC architecture 302 by providing real experience (e.g., real rewards based on final state of compressed student network).

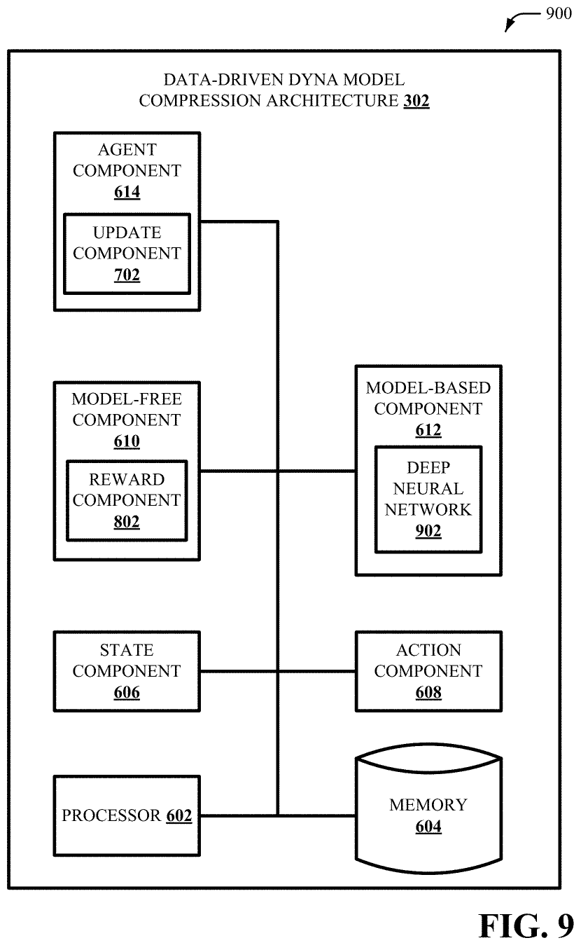

Now, consider FIG. 9. FIG. 9 illustrates a schematic block diagram of an example, non-limiting system 900 that facilitates automated neural network compression via an iterative hybrid reinforcement learning approach including a deep neural network in accordance with one or more embodiments described herein. As shown, the D3MC architecture 302 can, in various embodiments, have the same components as shown in FIG. 8, and can further comprise a deep neural network 902 in the model-based component 612. In various embodiments, the deep neural network 902 can learn an environmental model, which the model-based component 612 can then leverage to predict rewards of potential/contemplated compression actions and thereby minimize compression training time of the D3MC architecture 302. Those of ordinary skill in the art will appreciate that much of the above discussion regarding how model-based approaches compute rewards can be applied to the deep neural network 902 (e.g., background and/or decision-time planning, and so on). In one or more embodiments, the deep neural network 902 can receive one or more samples (e.g., final-state-and-reward tuples) from the model-free component 802 (and/or can receive the rewards from the model-free component 802 and can receive the final-state information from the state component 606, and so on). Based on these pairs (e.g., each pair including a final state of a compressed student network and the associated reward computed by the model-free component 610), the deep neural network 902 can be trained to predict the rewards that the model-free component 610 would compute for any given state information. This can, in some cases, take the form of supervised training of the deep neural network 902, in which the deep neural network 902 receives as input the final-state information and then iteratively changes its connection weights/biases (e.g., via backpropagation, stochastic gradient descent, and so on) to minimize an error function (e.g., the average squared differences between the actual output of the deep neural network 902 and the actual/correct rewards computed by the model-free component 610, and so on). In this way, the deep neural network 902 can serve as the environmental model for the model-based component 612, thereby allowing the model-based component 612 to predict at decision-time the reward (e.g., by learning the function r_{MB}:S→R) that would likely occur if a particular compression action and/or sequence of compression actions were taken. Training the D3MC architecture 302 in this way (e.g., via decision-time planning based on an environmental model) can help to reduce the overall convergence time of the D3MC architecture, meaning that it can converge on an optimal neural network compression policy more quickly than a compression architecture using model-free-only approaches could. Moreover, since the model-based component 612 can include the deep neural network 902 that can learn the reward model (e.g., the function r_{MB}:S→R) by being directly trained on the real experience outputted from the model-free component 610, the D3MC architecture 302 can avoid suffering a significant loss in compression accuracy. Thus, the subject claimed innovation can provide, in a sense, the best of both worlds: sufficiently high compression accuracy without inordinately long convergence times. This constitutes a significant technological benefit in the field of automated neural network compression.

In one or more embodiments, the deep neural network 902 can learn the function r_{MB}(xₜ), where xₜ={aₜ, l, k, ks, s, p, n}, and where aₜ is the action taken at time-step t, l is the layer type, k is the number of kernels, ks is the kernel size, s is the stride, p is the padding, and n is the number of trainable parameters. In such cases, the deep neural network 902 can estimate the function r_{MB} to predict a reward for actions that put the student network into state xₜ. Moreover, since there is no assumed distribution in the function r_{MB}, such as a Gaussian distribution, the model r_{MB} can be driven solely by the samples generated by the model-free component 610, which can be more representative of the heuristic data structure.

Those of ordinary skill in the art will appreciate that the deep neural network 902 can have any topology (e.g., fully connected, feedforward, recurrent, and so on) and/or any number of layers/neurons.

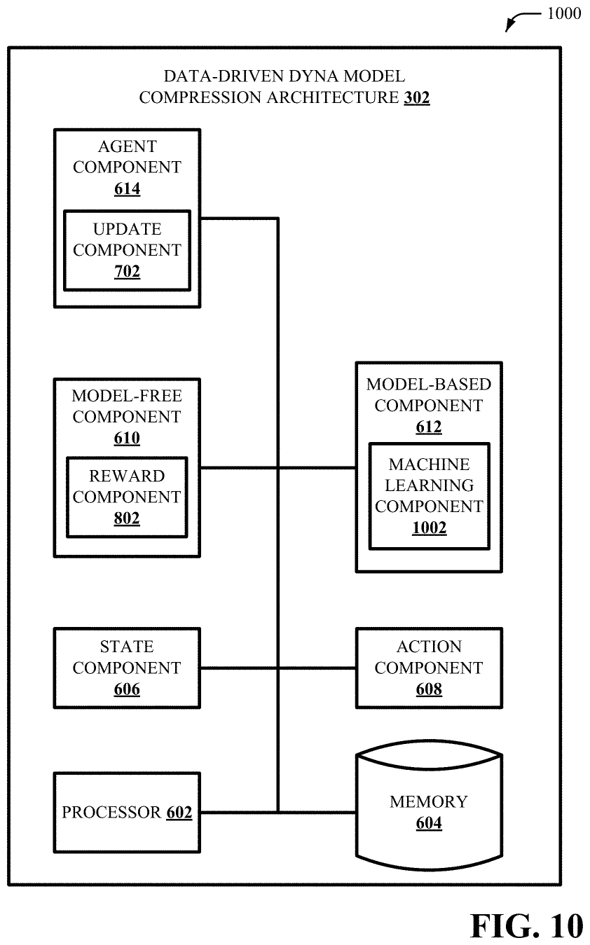

Now, consider FIG. 10. FIG. 10 illustrates a schematic block diagram of an example, non-limiting system 1000 that facilitates automated neural network compression via an iterative hybrid reinforcement learning approach including a machine learning component in accordance with one or more embodiments described herein. As shown, the D3MC architecture 302 can, in various embodiments, have the same components as shown in FIG. 8, and can further comprise a machine learning component 1002. In other words, while FIG. 9 contemplates embodiments containing a specific artificial intelligence structure to learn the environmental model for the model-based component 612 (e.g., the deep neural network 902), FIG. 10 contemplates embodiments in which other forms of artificial intelligence systems (e.g., machine learning component 1002) can be used to generate the environmental model based on the samples from the model-free component 610. Thus, consider the discussion of artificial intelligence below.

The embodiments of the present innovation herein can employ artificial intelligence (AI) to facilitate automating one or more features of the present innovation. The components can employ various AI-based schemes for carrying out various embodiments/examples disclosed herein. In order to provide for or aid in the numerous determinations (e.g., determine, ascertain, infer, calculate, predict, prognose, estimate, derive, forecast, detect, compute, and so on) of the present innovation, components of the present innovation can examine the entirety or a subset of the data to which it is granted access and can provide for reasoning about or determine states of the system, environment, and so on from a set of observations as captured via events and/or data. Determinations can be employed to identify a specific context or action, or can generate a probability distribution over states, for example. The determinations can be probabilistic; that is, the computation of a probability distribution over states of interest based on a consideration of data and events. Determinations can also refer to techniques employed for composing higher-level events from a set of events and/or data.

Such determinations can result in the construction of new events or actions from a set of observed events and/or stored event data, whether or not the events are correlated in close temporal proximity, and whether the events and data come from one or several event and data sources. Components disclosed herein can employ various classification (explicitly trained (e.g., via training data) as well as implicitly trained (e.g., via observing behavior, preferences, historical information, receiving extrinsic information, and so on)) schemes and/or systems (e.g., support vector machines, neural networks, expert systems, Bayesian belief networks, fuzzy logic, data fusion engines, and so on) in connection with performing automatic and/or determined action in connection with the claimed subject matter. Thus, classification schemes and/or systems can be used to automatically learn and perform a number of functions, actions, and/or determinations.

A classifier can map an input attribute vector, z=(z1, z2, z3, z4, zn), to a confidence that the input belongs to a class, as by f(z)=confidence(class). Such classification can employ a probabilistic and/or statistical-based analysis (e.g., factoring into the analysis utilities and costs) to determine an action to be automatically performed. A support vector machine (SVM) can be an example of a classifier that can be employed. The SVM operates by finding a hyper-surface in the space of possible inputs, where the hyper-surface attempts to split the triggering criteria from the non-triggering events. Intuitively, this makes the classification correct for testing data that is near, but not identical to training data. Other directed and undirected model classification approaches include, e.g., naïve Bayes, Bayesian networks, decision trees, neural networks, fuzzy logic models, and/or probabilistic classification models providing different patterns of independence, any of which can be employed. Classification as used herein also is inclusive of statistical regression that is utilized to develop models of priority.

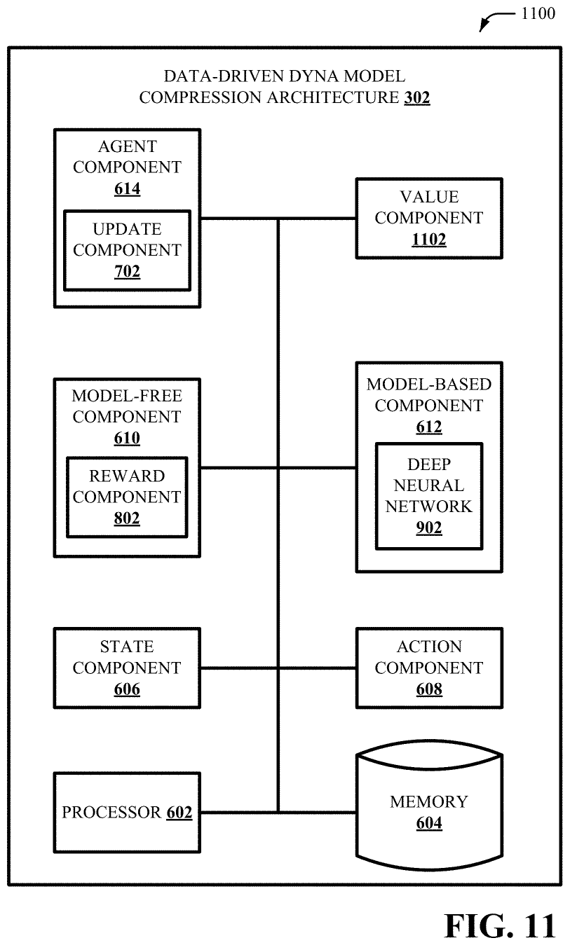

Now, consider FIG. 11. FIG. 11 illustrates a schematic block diagram of an example, non-limiting system 1100 that facilitates automated neural network compression via an iterative hybrid reinforcement learning approach including a value component in accordance with one or more embodiments described herein. As shown, the D3MC architecture 302 can, in various embodiments, include the same components as shown in FIG. 9, and can further comprise a value component 1102. In such cases, the value component 1102 can help implement an actor-critic policy optimization approach in the D3MC architecture 302, thereby helping to even further reduce compression training time. As one of ordinary skill in the art will appreciate, actor-critic optimization can, in some cases, be formulated as follows:

\vec{θ}ₜ₊₁=\vec{θ}ₜ+α∇J(\vec{θ}ₜ)

where

∇J(\vec{θ}ₜ)=(Rₜ₊₁+γv(Sₜ₊₁, \vec{w})−v(Sₜ, \vec{w}))∇lnπ(Aₜ|Sₜ, \vec{θ}ₜ)

and where γ is the discount rate, v is an estimated/learned state-value function, and \vec{w} is a vector of parameters defining the state-value function. Again, these formulas are exemplary only, and those of skill will understand that other forms, notations, and/or variations are possible and in accordance with the present disclosure.

Now, in one or more embodiments, the value component 1102 can learn and/or generate a state-value function v (and/or an action-value function) that can be used to update the compression policy of the agent component 614. In order to learn the state-value function, any suitable methods known in the art can be employed (e.g., semi-gradient temporal difference methods, any other temporal difference methods, eligibility traces, n-step bootstrapping, dynamic programming, Monte Carlo methods, SARSA methods, Expected SARSA methods, Q-learning methods, stochastic gradient methods, and so on).

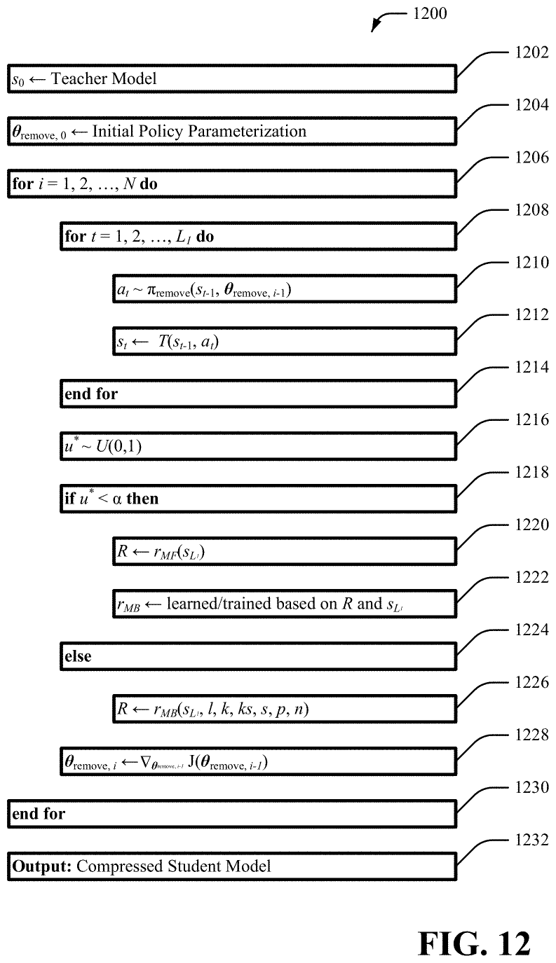

Now, consider FIG. 12. FIG. 12 illustrates pseudocode of an example, non-limiting computer-implemented algorithm 1200 that facilitates automated neural network compression via an iterative hybrid reinforcement learning approach in accordance with one or more embodiments described herein. At 1202, the initial state s₀ of the student network (e.g., the network being compressed) can be the state of the teacher network/model. At 1204, the initial removal policy parameterization \vec{θ}_{remove,0} (e.g., the parameters of the compression policy that determines whether to remove layers) can have some beginning initialization values. In some cases, the parameters can be randomly initialized. At 1206, a for-loop set to run N times can be entered with index i. At 1208, a nested for-loop set to run L₁ times (e.g., where L₁ can be the number of layers in the student network, or in some cases L can represent time-steps, and so on) can be entered with index t. At 1210, a compression action aₜ can be taken for each t from 1 to L₁. As shown, the action aₜ can be chosen by the removal policy πᵣₑₘₒᵥₑ(sₜ₋₁, \vec{θ}_{remove,i-1}) based on the previous (e.g., before the policy update at index i) removal policy parameterization \vec{θ}_{remove,i-1} and the previous (e.g., before aₜ is taken) state sₜ₋₁. At 1212, the next state sₜ can be computed based on the previous state sₜ₋₁ and the action just taken aₜ according to the transition function T, which can be deterministic. At 1214, the nested for-loop can end, which can leave the student network in state s_{L}_{₁}. At 1216, a random number u* can be chosen from the interval [0,1] with uniform probability. At 1218, an if-loop can be entered, asking whether the random number u* is less than some value α. At 1220, if the if-condition is satisfied, a reward R can be computed using the model-free reward function r_{MF}, discussed above, and the compressed state of the student network s_{L}_{₁}. At 1222, if the if-loop condition is satisfied, the model-based function r_{MB} can be trained/learned, as discussed above, based on the reward R computed by the model-free reward function r_{MF} and the compressed state of the student network s_{L}_{₁}. At 1224, the algorithm can determine whether the random number u* is not less than α. At 1226, if that is true, the reward R can be predicted by the model-based reward function r_{MB} based on the compressed state of the student network s_{L}_{₁}, the layer type l, the number of kernels k, the kernel size ks, the stride s, the padding p, and the number of trainable parameters n. At 1228, the updated policy \vec{θ}_{remove,i} can be computed based on the gradient of the performance measure ∇_{\vec{θ}}_{_{remove,i−1}}J(\vec{θ}_{remove,i-1}). 1230, the first for-loop can finally end. Finally, at 1232, the algorithm can output the optimally compressed student network/model.

Those of ordinary skill in the art will appreciate that this algorithm is exemplary only; fewer steps and/or additional steps and/or other steps can be included, possibly in different orders, in accordance with this disclosure.

For simplicity of explanation, the computer-implemented methodologies are depicted and described as a series of acts. It is to be understood and appreciated that the subject innovation is not limited by the acts illustrated and/or by the order of acts; for example, acts can occur in various orders and/or concurrently, and with other acts not presented and described herein. Furthermore, not all illustrated acts can be required to implement the computer-implemented methodologies in accordance with the disclosed subject matter. In addition, those skilled in the art will understand and appreciate that the computer-implemented methodologies could alternatively be represented as a series of interrelated states via a state diagram or events. Additionally, it should be further appreciated that the computer-implemented methodologies disclosed herein and throughout this specification are capable of being stored on an article of manufacture to facilitate transporting and transferring such computer-implemented methodologies to computers. The term article of manufacture, as used herein, is intended to encompass a computer program accessible from any computer-readable device or storage media.

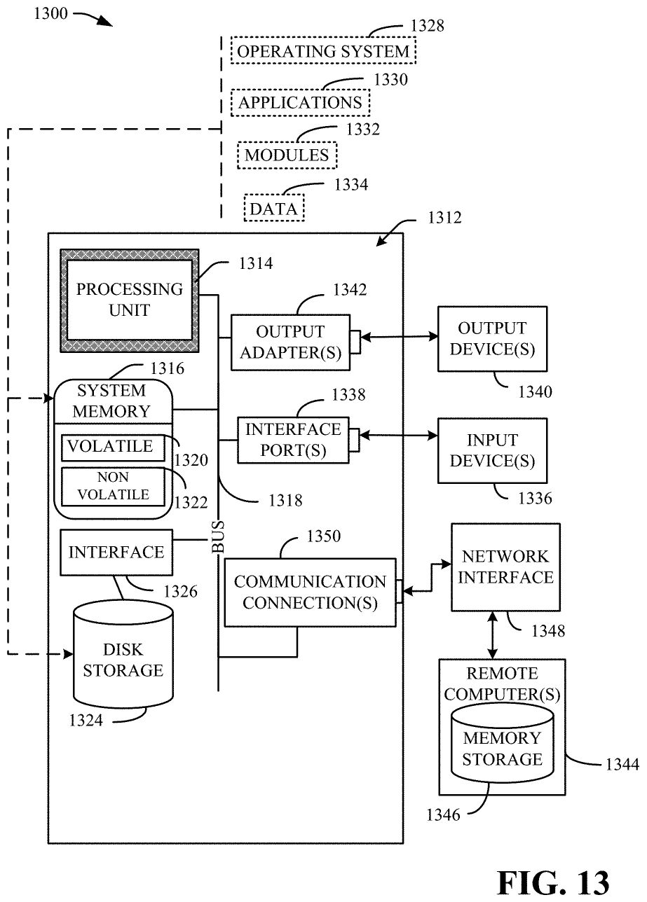

In order to provide a context for the various aspects of the disclosed subject matter, FIG. 13 as well as the following discussion are intended to provide a general description of a suitable environment in which the various aspects of the disclosed subject matter can be implemented. FIG. 13 illustrates a block diagram of an example, non-limiting operating environment in which one or more embodiments described herein can be facilitated. Repetitive description of like elements employed in other embodiments described herein is omitted for sake of brevity. With reference to FIG. 13, a suitable operating environment 1300 for implementing various aspects of this disclosure can also include a computer 1312. The computer 1312 can also include a processing unit 1314, a system memory 1316, and a system bus 1318. The system bus 1318 couples system components including, but not limited to, the system memory 1316 to the processing unit 1314. The processing unit 1314 can be any of various available processors. Dual microprocessors and other multiprocessor architectures also can be employed as the processing unit 1314. The system bus 1318 can be any of several types of bus structure(s) including the memory bus or memory controller, a peripheral bus or external bus, and/or a local bus using any variety of available bus architectures including, but not limited to, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Card Bus, Universal Serial Bus (USB), Advanced Graphics Port (AGP), Firewire (IEEE 1394), and Small Computer Systems Interface (SCSI). The system memory 1316 can also include volatile memory 1320 and nonvolatile memory 1322. The basic input/output system (BIOS), containing the basic routines to transfer information between elements within the computer 1312, such as during start-up, is stored in nonvolatile memory 1322. By way of illustration, and not limitation, nonvolatile memory 1322 can include read only memory (ROM), programmable ROM (PROM), electrically programmable ROM (EPROM), electrically erasable programmable ROM (EEPROM), flash memory, or nonvolatile random access memory (RAM) (e.g., ferroelectric RAM (FeRAM). Volatile memory 1320 can also include random access memory (RAM), which acts as external cache memory. By way of illustration and not limitation, RAM is available in many forms such as static RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM), and Rambus dynamic RAM.

Computer 1312 can also include removable/non-removable, volatile/non-volatile computer storage media. FIG. 13 illustrates, for example, a disk storage 1324. Disk storage 1324 can also include, but is not limited to, devices like a magnetic disk drive, floppy disk drive, tape drive, Jaz drive, Zip drive, LS-100 drive, flash memory card, or memory stick. The disk storage 1324 also can include storage media separately or in combination with other storage media including, but not limited to, an optical disk drive such as a compact disk ROM device (CD-ROM), CD recordable drive (CD-R Drive), CD rewritable drive (CD-RW Drive) or a digital versatile disk ROM drive (DVD-ROM). To facilitate connection of the disk storage 1324 to the system bus 1318, a removable or non-removable interface is typically used, such as interface 1326. FIG. 13 also depicts software that acts as an intermediary between users and the basic computer resources described in the suitable operating environment 1300. Such software can also include, for example, an operating system 1328. Operating system 1328, which can be stored on disk storage 1324, acts to control and allocate resources of the computer 1312. System applications 1330 take advantage of the management of resources by operating system 1328 through program modules 1332 and program data 1334, e.g., stored either in system memory 1316 or on disk storage 1324. It is to be appreciated that this disclosure can be implemented with various operating systems or combinations of operating systems. A user enters commands or information into the computer 1312 through input device(s) 1336. Input devices 1336 include, but are not limited to, a pointing device such as a mouse, trackball, stylus, touch pad, keyboard, microphone, joystick, game pad, satellite dish, scanner, TV tuner card, digital camera, digital video camera, web camera, and the like. These and other input devices connect to the processing unit 1314 through the system bus 1318 via interface port(s) 1338. Interface port(s) 1338 include, for example, a serial port, a parallel port, a game port, and a universal serial bus (USB). Output device(s) 1340 use some of the same type of ports as input device(s) 1336. Thus, for example, a USB port can be used to provide input to computer 1312, and to output information from computer 1312 to an output device 1340. Output adapter 1342 is provided to illustrate that there are some output devices 1340 like monitors, speakers, and printers, among other output devices 1340, which require special adapters. The output adapters 1342 include, by way of illustration and not limitation, video and sound cards that provide a means of connection between the output device 1340 and the system bus 1318. It should be noted that other devices and/or systems of devices provide both input and output capabilities such as remote computer(s) 1344.

Computer 1312 can operate in a networked environment using logical connections to one or more remote computers, such as remote computer(s) 1344. The remote computer(s) 1344 can be a computer, a server, a router, a network PC, a workstation, a microprocessor based appliance, a peer device or other common network node and the like, and typically can also include many or all of the elements described relative to computer 1312. For purposes of brevity, only a memory storage device 1346 is illustrated with remote computer(s) 1344. Remote computer(s) 1344 is logically connected to computer 1312 through a network interface 1348 and then physically connected via communication connection 1350. Network interface 1348 encompasses wire and/or wireless communication networks such as local-area networks (LAN), wide-area networks (WAN), cellular networks, etc. LAN technologies include Fiber Distributed Data Interface (FDDI), Copper Distributed Data Interface (CDDI), Ethernet, Token Ring and the like. WAN technologies include, but are not limited to, point-to-point links, circuit switching networks like Integrated Services Digital Networks (ISDN) and variations thereon, packet switching networks, and Digital Subscriber Lines (DSL). Communication connection(s) 1350 refers to the hardware/software employed to connect the network interface 1348 to the system bus 1318. While communication connection 1350 is shown for illustrative clarity inside computer 1312, it can also be external to computer 1312. The hardware/software for connection to the network interface 1348 can also include, for exemplary purposes only, internal and external technologies such as, modems including regular telephone grade modems, cable modems and DSL modems, ISDN adapters, and Ethernet cards.

Embodiments can be a system, a computer-implemented method, an apparatus and/or a computer program product at any possible technical detail level of integration. The computer program product can include a computer readable storage medium (or media) having computer readable program instructions thereon for causing a processor to carry out aspects of the herein described embodiments. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network can comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of embodiments can be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions can execute entirely on the user's computer, partly on the user's computer, as a stand-alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider). In some embodiments, electronic circuitry including, for example, programmable logic circuitry, field-programmable gate arrays (FPGA), or programmable logic arrays (PLA) can execute the computer readable program instructions by utilizing state information of the computer readable program instructions to personalize the electronic circuitry, in order to perform aspects of the subject innovation.

Aspects are described herein with reference to flowchart illustrations and/or block diagrams of methods, apparatus (systems), and computer program products according to embodiments. It will be understood that each block of the flowchart illustrations and/or block diagrams, and combinations of blocks in the flowchart illustrations and/or block diagrams, can be implemented by computer readable program instructions. These computer readable program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions can also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks. The computer readable program instructions can also be loaded onto a computer, other programmable data processing apparatus, or other device to cause a series of operational acts to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, computer-implemented methods, and computer program products according to various embodiments. In this regard, each block in the flowchart or block diagrams can represent a module, segment, or portion of instructions, which comprises one or more executable instructions for implementing the specified logical function(s). In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the subject matter has been described above in the general context of computer-executable instructions of a computer program product that runs on a computer and/or computers, those skilled in the art will recognize that this disclosure also can or can be implemented in combination with other program modules. Generally, program modules include routines, programs, components, data structures, etc. that perform particular tasks and/or implement particular abstract data types. Moreover, those skilled in the art will appreciate that the inventive computer-implemented methods can be practiced with other computer system configurations, including single-processor or multiprocessor computer systems, mini-computing devices, mainframe computers, as well as computers, hand-held computing devices (e.g., PDA, phone), microprocessor-based or programmable consumer or industrial electronics, and the like. The illustrated aspects can also be practiced in distributed computing environments where tasks are performed by remote processing devices that are linked through a communications network. However, some, if not all aspects of this disclosure can be practiced on stand-alone computers. In a distributed computing environment, program modules can be located in both local and remote memory storage devices.

As used in this application, the terms “component,” “system,” “platform,” “interface,” and the like, can refer to and/or can include a computer-related entity or an entity related to an operational machine with one or more specific functionalities. The entities disclosed herein can be either hardware, a combination of hardware and software, software, or software in execution. For example, a component can be, but is not limited to being, a process running on a processor, a processor, an object, an executable, a thread of execution, a program, and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which is operated by a software or firmware application executed by a processor. In such a case, the processor can be internal or external to the apparatus and can execute at least a part of the software or firmware application. As yet another example, a component can be an apparatus that provides specific functionality through electronic components without mechanical parts, wherein the electronic components can include a processor or other means to execute software or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit or device comprising, but not limited to, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Further, processors can exploit nano-scale architectures such as, but not limited to, molecular and quantum-dot based transistors, switches and gates, in order to optimize space usage or enhance performance of user equipment. A processor can also be implemented as a combination of computing processing units. In this disclosure, terms such as “store,” “storage,” “data store,” data storage,” “database,” and substantially any other information storage component relevant to operation and functionality of a component are utilized to refer to “memory components,” entities embodied in a “memory,” or components comprising a memory. It is to be appreciated that memory and/or memory components described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory, or nonvolatile random access memory (RAM) (e.g., ferroelectric RAM (FeRAM). Volatile memory can include RAM, which can act as external cache memory, for example. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM), and Rambus dynamic RAM (RDRAM). Additionally, the disclosed memory components of systems or computer-implemented methods herein are intended to include, without being limited to including, these and any other suitable types of memory.

What has been described above include mere examples of systems and computer-implemented methods. It is, of course, not possible to describe every conceivable combination of components or computer-implemented methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim. The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An artificial neural network compression system, comprising:
a processor that executes computer-executable instructions stored on a computer-readable memory;
a reinforcement learning (RL) agent component that determines which compression actions to perform;
a model-free component comprising:
a first state component that receives electronic data indicating a state of a neural network to be compressed; and
a first action component that performs one or more compression actions determined by the RL agent component on the neural network to compress the neural network into a compressed neural network; and
a model-based component comprising:
a second state component that receives electronic data indicating a state of the neural network to be compressed; and
a second action component that performs one or more compression actions determined by the RL agent component on the neural network to compress the neural network into a compressed neural network;
wherein the model-free component computes, in some proportion of iterations, a first reward signal, quantifying how well the neural network was compressed, based on a compression ratio and a model performance metric of the compressed neural network for the first state component and the first action component;
wherein the model-based component predicts, in some remaining proportion of iterations, a second reward signal, quantifying how well the neural network was compressed, based on a compression model learned from the first state component and the first action component; and
wherein the RL agent component iteratively updates based on one or more first reward signals computed by the model-free component and one or more second reward signals predicted by the model-based component until convergence.

2. The system of claim 1, wherein the proportion of iterations in which the model-free component computes a first reward signal is decayed over time.

3. The system of claim 1, further comprising a deep neural network in the model-based component that learns a functional approximation of state and action to predict reward signal and is trained on the first state component and the first action component.

4. The system of claim 1, wherein the one or more compression actions includes at least one of removing a layer in the neural network or adjusting parameters in the neural network.

5. The system of claim 1, wherein the RL agent component is updated by at least one optimization method.

6. The system of claim 1, wherein the model-based component predicts the reward signal by planning.

7. The system of claim 1, wherein the second state component is related to the first state component, the second action component is related to the first action component, and the second reward signal is related to the first state component and the first action component.

8. A computer-implemented method for compressing artificial neural networks, comprising the following acts:
receiving as input an original neural network to be compressed;
performing one or more compression actions by a reinforcement learning (RL) agent to compress the original neural network into a compressed neural network;
generating a reward signal that quantifies how well the original neural network was compressed by one of the following:
i) computing, in some proportion of compression iterations, the reward signal in model-free fashion based on a compression ratio and an accuracy ratio of the compressed neural network;
ii) predicting, in some remaining proportion of compression iterations, the reward signal in model-based fashion based on a compression model learned from reward signals computed in model-free fashion;
updating the RL agent based on the reward signal; and
iterating respective prior acts until convergence.

9. The computer-implemented method of claim 8, further comprising decaying over time the proportion of compression iterations in which the reward signal is computed in model-free fashion.

10. The computer-implemented method of claim 8, wherein the compression model is learned by a deep neural network trained on rewards computed in model-free fashion.

11. The computer-implemented method of claim 8, wherein the one or more compression actions includes at least one of removing a layer in the original neural network or adjusting parameters in the original neural network.

12. The computer-implemented method of claim 8, wherein the RL agent is updated by at least one optimization method.

13. The computer-implemented method of claim 8, wherein the predicting the reward signal in model-based fashion is performed by planning.

14. The computer-implemented method of claim 8, wherein the predicting the reward signal in model-based fashion is related to the computing the reward signal in model-free fashion.

15. A computer program product that compresses artificial neural networks, comprising a non-transitory computer-readable storage medium having program instructions embodied therewith, the program instructions executable by a processing component to cause the processing component to:
receive as input an original neural network to be compressed;
perform one or more compression actions by a reinforcement learning (RL) agent to compress the original neural network into a compressed neural network;
generate a reward signal that quantifies how well the original neural network was compressed by one of the following:
i) computing, in some proportion of compression iterations, the reward signal in model-free fashion based on a compression ratio and an accuracy ratio of the compressed neural network;
ii) predicting, in some remaining proportion of compression iterations, the reward signal in model-based fashion based on a compression model learned from reward signals computed in model-free fashion;
update the RL agent based on the reward signal; and
iterate respective prior acts until convergence.

16. The computer program product of claim 15, wherein the computer-executable instructions further cause the processing component to decay over time the proportion of compression iterations in which reward signals are computed in model-free fashion.

17. The computer program product of claim 15, wherein the compression model is learned by a deep neural network trained on rewards computed in model-free fashion.

18. The computer program product of claim 15, wherein the one or more compression actions includes at least one of removing a layer in the original neural network or adjusting parameters in the original neural network.
